(19) United States
(12) Patent Application Publication
(10) Pub. No.: US 2009/0140955 A1
(43) Pub. Date: Jun. 4, 2009

(54) LIGHT-EMITTING ELEMENT AND DISPLAY DEVICE

(75) Inventors: Kenji Nakamura, Saitama (JP); Takuya Hata, Saitama (JP); Atsushi Yoshizawa, Saitama (JP); Katsunari Obata, Tokyo (JP); Hiroyuki Endo, Tokyo (JP)

Correspondence Address: SUGHRUE MION, PLLC, 2100 PENNSYLVANIA AVENUE, N.W., SUITE 800, WASHINGTON, DC, 20037, US

(73) Assignees: PIONEER CORPORATION, Meguro-ku, Tokyo (JP); DAI NIPPON PRINTING CO., LTD., Shinjuku-ku, Tokyo (JP); NEC CORPORATION, Minato-ku, Tokyo (JP)

(21) Appl. No.: 12/089,841

(22) PCT Filed: Oct. 12, 2006
(86) PCT No.: PCT/JP2006/320803

§ 371 Date: Jul. 17, 2008

(30) Foreign Application Priority Data
Oct. 14, 2005 (JP) 2005-300596

(51) Int. Cl. G09G 3/30; H01J 1/62

(52) U.S. Cl. 345/76; 313/504

(57) ABSTRACT

A light-emitting element that comprises a light emission layer that is deposited between first and second electrodes that lie opposite one another in parallel, an organic semiconductor layer that is deposited between the light emission layer and the first electrode, and an auxiliary electrode that is disposed via an insulation layer on the opposite side of the face of the first electrode opposite the second electrode, the light-emitting element further comprising a third electrode that is disposed inside the organic semiconductor layer.

### TECHNICAL FIELD

The present invention relates to a light-emitting element and display device that utilizes a compound with carrier transportability (mobility of holes or electrons) and comprises a semiconductor layer made of such a compound.

### BACKGROUND ART

Currently, there is a focus on light-emitting elements that utilize electroluminescence (called simply ‘EL’ hereinbelow) by the re-coupling of carriers (holes or electrons) in a material, for example, which are emitted upon application of an electric field. For example, EL display devices in which a display panel formed by injection-type organic EL elements that employ organic compound materials is installed have been developed. Organic EL elements include red EL elements that have a structure that emits light of a red color, green EL elements that have a structure that emits light of a green color, and yellow EL elements with a structure that emits light of a yellow color. A color display device can be implemented if these three organic EL elements that emit light in red, blue, and green (RGB) form one pixel light-emitting unit and a plurality of pixels are disposed in a matrix shape on a panel section. As drive systems for a display panel formed by this color display device, a passive matrix drive type and active matrix drive type are known. In comparison with a passive matrix type EL display device, an active matrix drive type EL display device has the benefit of having low power consumption little crosstalk between pixels and is particularly suited to a large screen display device and high definition display device.

A display panel of an active matrix drive type EL display device has anode supply lines, cathode supply lines, and scanning lines that are charged with horizontal scanning and signal lines that are arranged intersecting each of the scanning lines formed in the form of a grating. RGB subpixels are formed at the respective RGB intersections of the scanning lines and signal lines. A scanning line is connected to the gate of the Field Effect Transistor (FET) used for the scanning line selection for each subpixel, a signal line is connected to the drain of the FET, and the gate of the FET used for light emission driving is connected to the source of the FET. A drive voltage is applied via an anode supply line to the source of the light-emission drive FET and the anode terminal of the EL element is connected to the drain. A capacitor is connected between the gate and source of the light-emitting drive FET. Furthermore, a ground potential is applied via the anode supply line to the cathode terminal of the EL element.

For example, in prior inventions (See Japanese Patent Application Laid Open No. 2002-343578), as shown in FIG. 1, in the case of a light-emitting body that comprises an anode and a cathode that is installed at least partly facing the anode via a light-emitting material layer on a substrate, in a structure in which an auxiliary electrode is formed via an insulation layer on the face opposite the face opposing the cathode via the light-emitting material layer of the anode, a voltage is applied between the auxiliary electrode and cathode so as to face in the same direction as the direction of the voltage applied between the anode and cathode. In the case of a multicolored organic EL display that uses this action, changing the material used for the light-emitting layer and voltage control that is adapted to the respective light-emitting material properties are required in order to change the brightness.

### DISCLOSURE OF THE INVENTION

A conventional organic light-emitting element as typified by an organic EL element is basically an element that exhibits the characteristics of a diode and the majority of such manufactured light-emitting elements are passive-matrix drive-type light-emitting elements. In passive-matrix driving, a momentarily high brightness is required in order to perform line-sequential driving and it has proven difficult to obtain a high-definition display device because the limit count of the scan lines is limited. In recent years, organic EL displays that employ TFTs that use polysilicon or the like have been studied. However, organic EL displays do not lend themselves to an increased screen size because the process temperature is high and the fabrication costs per unit area increase. Further, there have been problems, i.e. while, on the one hand, the aperture drops because two or more transistors and one or more condensers must be arranged in one pixel in order to actively drive the organic EL by using TFTs, the organic EL elements must be made to emit light at a high brightness while performing voltage control that is suited to the respective light-emitting material characteristics.

An example of the problem to be solved by the present invention is that of providing a display device and light-emitting element capable of increasing the light-emitting efficiency of the organic EL element while performing voltage control that is suited to the respective light-emitting material characteristics.

The light-emitting element according to claim 1 is a light-emitting element that comprises a light emission layer that is deposited between first and second electrodes that lie opposite one another in parallel; an organic semiconductor layer that is deposited between the light emission layer and the first electrode; and an auxiliary electrode that is disposed via an insulation layer on the opposite side of the face of the first electrode opposite the second electrode, the light-emitting element further comprising: a third electrode that is disposed inside the organic semiconductor layer.

The display device according to claim 10 is a display device in which a plurality of light-emitting sections are disposed in a matrix shape, wherein each of the light-emitting sections is a light-emitting element that comprises a light emission layer that is deposited between first and second electrodes that lie opposite one another in parallel, an organic semiconductor layer that is deposited between the light emission layer and the first electrode, and an auxiliary electrode that is disposed via an insulation layer on the opposite side of the face of the first electrode opposite the second electrode, the light-emitting element further comprising: a third electrode that is disposed inside the organic semiconductor layer.

Conventional elements have hitherto performed control of brightness grayscales of a display device by obtaining a variation in the light emission brightness by applying a voltage to the auxiliary electrode while fixing the voltage that is applied across the anode and cathode. With a light-emitting element of the above constitution, a third electrode of a different electrical connection destination is provided in addition to the first and second electrodes. For example, the first and third electrodes are anodes and the fact that the current value and light emission intensity changes as a result of supplying a different potential to two anodes is used and finer grayscale control can be executed.

### BRIEF DESCRIPTION OF THE DRAWINGS

FIG. 1 is a partial cross-sectional view of a conventional organic EL element.

FIG. 2 is a partial cross-sectional view of an organic EL element of an embodiment of the present invention.

FIG. 3 is a partial cross-sectional view of an organic EL element of another embodiment of the present invention.

FIG. 4 is a partial cross-sectional view of an organic EL element of another embodiment of the present invention.

FIG. 5 is a partial cross-sectional view of an organic EL element of another embodiment of the present invention.

FIG. 6 is a partial cross-sectional view of an organic EL element of another embodiment of the present invention.

FIG. 7 is an equivalence circuit diagram showing a subpixel light emission section of an organic EL display device of another embodiment of the present invention.

FIG. 8 is a constitutional view of an organic EL display panel in which the plurality of light-emitting sections in FIG. 7 are arranged as a matrix and used as pixels.

FIG. 9 is a partial planar view of an organic EL element of another embodiment of the present invention.

### DETAILED DESCRIPTION OF THE INVENTION

An organic EL display panel will be described hereinbelow with reference to the drawings as an example of a light-emitting element of an embodiment of the present invention.

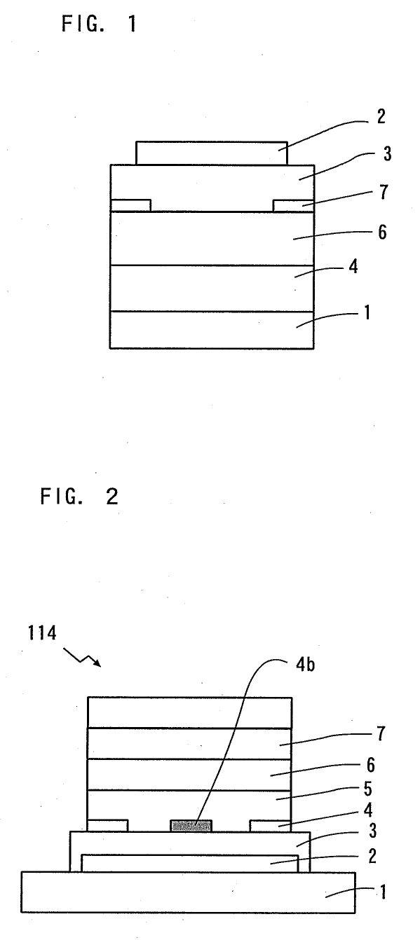

FIG. 2 shows an organic EL element 114 of light-emitting elements formed on a substrate 1 that comprises a light emission layer 6 that is deposited between a pair of opposing first and second electrodes (anode 4 and cathode 7) of the embodiment of the present invention.

The organic EL element 114 is obtained by forming on a substrate 1, in order, an auxiliary electrode 2, an insulation layer 3, the anode 4 (first electrode) and a second anode 4b (third electrode), a hole injection layer 5, a light emission layer 6, and cathode 7 (second electrode). Here, the hole injection layer 5 belongs to an organic semiconductor layer that exhibits carrier transportability. In addition to a hole injection layer, an organic semiconductor layer that exhibits carrier transportability may be a hole transport layer, stacked layers thereof, or a block layer or the like, for example. In addition, although an organic semiconductor layer that exhibits carrier transportability is not illustrated, one such organic semiconductor layer may be, for example, an electron injection layer, an electron transport layer, or stacked layers thereof, or a block layer and so forth which is inserted between the cathode 7 and light-emitting layer 6.

The anode 4 and second anode 4b are deposited in a pattern that has a grating shape, a comb shape or a blind shape. Thus, the conditions are favorable for carriers to pass through the organic semiconductor layer. That is, the anode 4 of the organic semiconductor layer 5 of a hole injection layer or hole transport layer is formed to demarcate the pattern for carriers to pass through the organic semiconductor layer.

Further, the first anode 4 and second anode 4b are each connected to the first and second power supplies of other circuits that are each independent.

Thus, while the voltage applied across the anode and cathode in element structures of the prior art is fixed, control of the brightness grayscales of the display device is performed by obtaining a variation in the light emission brightness by applying a voltage to the auxiliary electrode. However, according to this embodiment, two or more anodes (or cathodes) of different electrical connections are provided and an organic EL element that allows finer grayscale control to be performed in conjunction with brightness grayscale control by means of the voltage applied to the auxiliary electrode as a result of changing the current value and light emission intensity by supplying different potentials to the anodes (or cathodes) is obtained.

This embodiment employs vacuum deposition or the like to form an auxiliary electrode 2 that is patterned on a glass substrate and forms the insulation layer 3 and hole injection layer 5 on the auxiliary electrode 2 by using vacuum deposition or spin-coating or the like. The deposition quality of the coating-type hole injection material is improved by forming the anode after forming the hole injection layer and the current flowing to the cathode 7 when a voltage is not applied to the anode (when same is OFF) and the light emission intensity can also be reduced for a hole injection material that is not fixed in the coating-type hole injection material and which is formed by vacuum deposition. As a result, the current when a voltage is applied to the anode (when same is ON), the light emission intensity and the current when the anode is OFF, and the respective ratios of the light emission intensity improve.

The material of the substrate 1 is not limited to a semitransparent material such as glass, quartz and a plastic material such as polystyrene. Nontransparent materials such as silicon and aluminum, thermally curable resins such as a phenol resin, and a thermoplastic resin such as polycarbonate can be used.

The electrode materials of the auxiliary electrode 2, anode 4, second anode 4b, and cathode 7 include metals or alloys thereof such as Ti, Al, Li:Al, Cu, Ni, Ag, Mg: Ag, Au, Pt, Pd, Ir, Cr, Mo, W, and Ta. Alternatively, conductive polymers such as polyaniline or PEDT:PSS can be used. Otherwise, an oxide transparent conductive thin film can be used whose main component is any of indium tin oxide (ITO), indium zinc oxide (IZO), indium oxide (In₂O₃), zinc oxide (ZnO), and tin oxide (SnO₂), for example, but the oxide transparent conductive thin film is not limited to the aforementioned compounds. Furthermore, the thickness of each electrode is preferably on the order of 10 to 500 nm. A range of 50 to 300 nm in particular is suitable for the material of the cathode 7 and the auxiliary electrode 2. A range on the order of 10 to 200 nm in particular is suitable for the material of the cathode 7. The electrode material is preferably manufactured by vacuum deposition or sputtering.

The difference between the value of the work function of the anode material (4, 4b) and the value of the ionization potential of the organic semiconductor layer 5 is preferably no more than 0.5 eV. The light emission layer emits light when a voltage is applied between the auxiliary electrode and the electrode of the organic semiconductor layer in a direction that is the opposite of the direction of the voltage applied across the anode and cathode. The value of the work function of the material of the anode is selected from values that are smaller than the value of the ionization potential of the organic semiconductor layer 5.

A variety of insulating materials as typified by SiO₂ and Si₃N₄ can be used for the insulation layer 3. However, an inorganic oxide film with a high dielectric constant in particular is preferable. Inorganic oxides include silicon oxide, aluminum oxide, tantalum oxide, titanium oxide, tin oxide, vanadium oxide, barium-strontium titanate, barium zirconate titanate, lead zirconate titanate, lead lanthanum titanate, strontium titanate, barium titanate, barium magnesium fluoride, bismuth titanate, strontium bismuth titanate, strontium bismuth tantalate, bismuth tantalate niobate, and yttrium trioxide. Among these inorganic oxides, silicon oxide, aluminum oxide, tantalum oxide, and titanium oxide are preferable. Inorganic nitrides such as silicon nitride and aluminum nitride can also be preferably used. Furthermore, organic compound films such as polyimides, polyamides, polyesters, polyacrylates, and optical radical polymerization systems, optically curable resins of optical cation polymerization systems, or copolymers that include an acrylonitryl component, polyvinylphenol, polyvinyl alcohol, novolac resin, and cyanoethylpullulan, a polymer body, phosphazene comprising an elastomer body, and so forth, can also be used.

The positive-hole injection layer 5 has a function that facilitates the injection of holes from the anode 4 and a function for transferring holes stably. As for the material of the positive-hole injection layer 5, a porphyrin derivative as typified by copper phthalocyanine (CuPc), a polyacene as typified by petacene, an arylamine polymer known as starburst amine as typified by m-TDATA are often used in a low molecular system. Further, a layer whose conductivity is raised by mixing Lewis acid and tetracyanoquinodimethane (F4-TCNQ) or the like with a porphyrin derivative or triphenylamine derivative or the like can also be used. Here, the mixing ratio is preferably a weight ratio with mixing being performed at a rate of 5 to 95%. Further, in a high molecular system, a polymer material such as polyaniline (PANI), a polythiophene derivative (PEDOT), poly (3-hexylthiophene) (P3HT) can be used. Further, the hole injection layer 5 may be a mixed layer of these materials or stacked layers thereof.

The light emission layer 6 is made to contain a fluorescent material or phosphorescent material which is a compound with a light-emitting function. Fluorescent materials of this kind include at least one type selected from the compounds disclosed in Japanese Patent Application Laid Open No. 63-264692, for example, such as, for example, compounds such as quinacridone, rubrene, and styrene-based dye. Phosphorescent materials include the organic iridium complexes and organic platinum complexes in Appl. Phys. Lett., Volume 75, Page 4, 1999.

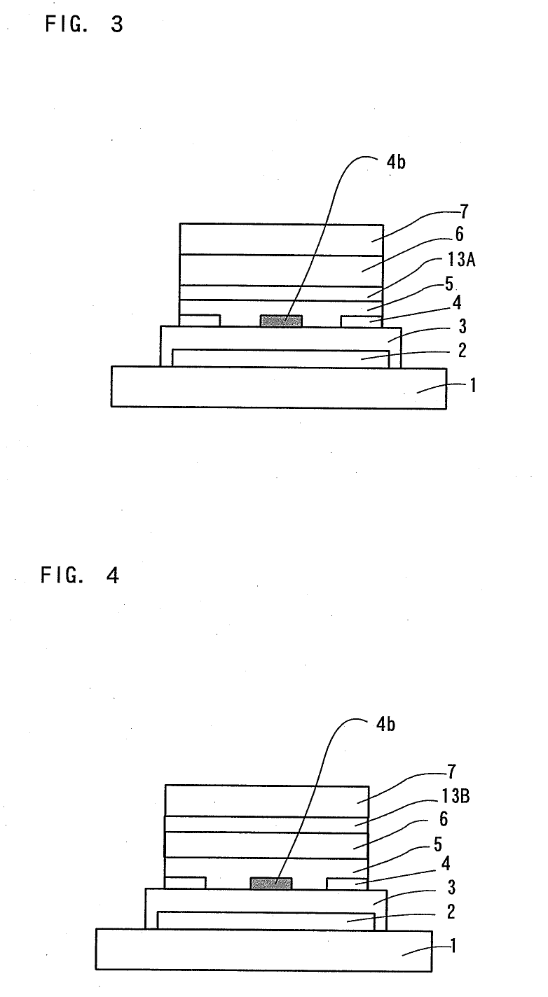

Further, as shown in FIG. 3, as a further embodiment, other than inserting the hole transport layer 13A as an organic semiconductor layer between the hole injection layer 5 and light emission layer 6, the EL element is the same element as the organic EL element 114 shown in FIG. 2. Materials for the hole transport layer 13A include triphenyldiamine derivatives, styrylamine derivatives, amine derivatives containing an aromatic ring, and carbazoyl derivatives and, polymer materials include polyvinylcarbazoyl and derivatives thereof, and polythiophene. Usage of two or more of these compounds may be combined. In addition, generally, the hole transport layer preferably employs an organic semiconductor material with a higher ionization potential Ip than the hole injection layer.

In addition, as shown in FIG. 4, there is a further embodiment which is the same element as the organic EL element 114 shown in FIG. 2 other than inserting an electron injection layer 13B as the organic semiconductor layer between the light emission layer 6 and cathode 7. Although not illustrated, an electron transport layer can also be provided between the electron injection layer and light emission layer in this embodiment. A quinoline derivative such as an organic metal complex in which an 8-quinolinol such as tris(8-quino-linato) aluminum (Alq3) or the derivative thereof is the ligand, an oxadiazone derivative, a perylene derivative, a pyridene derivative, a pirimidine derivative, a quinoxaline derivative, a diphenylquinone derivative, or a nitro-substituted fluorine derivative or the like can be used as the electron injection layer and/or electron transport layer. The electron injection layer and electron transport layer may be combined with the light emission layer 6 and, in this case, tris (8-quino-linato) aluminum or the like is preferably used. When the electron injection layer and electron transport layer are stacked and created, stacking is preferably performed in order with the compound with the largest electron affinity value starting with the cathode 7.

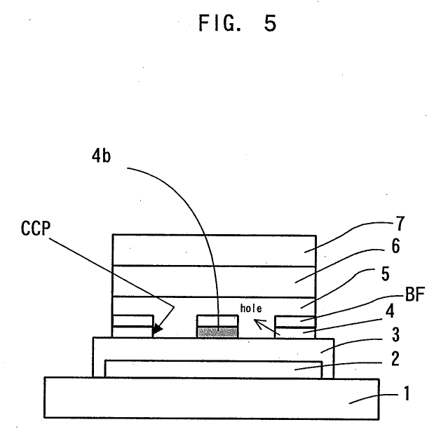

In addition, as shown in FIG. 5, a further embodiment is one with the same element as the organic EL element 114 shown in FIG. 2 other than the insertion of a carrier suppression layer BF inserted in contact between the first and second anodes 4 and 4b respectively and the hole injection layer 5. A carrier supply section CPP in which the respective anodes contact the hole injection layer 5 is demarcated by the carrier suppression layer BF (insulation layer, for example). In this case, the value of the work function of the carrier suppression layer BF is smaller than the value of the work function of the respective anodes. Here, the material of the carrier suppression layer BF is selected from among those materials having a larger work function value than the value of the ionization potential of the hole injection layer 5. In this embodiment, the carrier suppression layer BF, which comprises a metal material that is different from the metal material of the respective anodes, is stacked on the respective anodes and the path for the carriers injected into the hole injection layer 5 is controlled by the carrier suppression layer BF.

For the movement of carriers in the organic semiconductor, the carrier suppression layer BF is selected on the basis of the condition of the ionization potential, that is, the value of the work function (or ionization potential) between the work function of the contact electrode and the ionization potential of the organic semiconductor layer. This is because it is better to have a large energy barrier in order to suppress the movement of carriers.

With regard to the material of the carrier suppression layer BF used in this embodiment, more specifically, when the respective anodes with a work function Wf1 (eV) and the hole injection material (hole injection layer 5) with an ionization potential Ip1 (eV) and the carrier suppression layer BF with a work function Wf2 (eV) are stacked, Ip1 and Wf2 are preferably related such that Ip1>Wf2. As a result of inserting the carrier suppression layer BF, there is a barrier from the respective anodes to the organic semiconductor layers between which the carrier suppression layer BF is interposed and current does not readily flow.

Further, although Ip1 and Wf1 are desirably related such that Ip1<Wf1, Ip1≧Wf1 is also possible and the difference between Ip1 and Wf1 may be equal to or less than 0.5 eV. Although the hole injection at the face where the hole injection layer 5 and the respective anodes make contact must be obstructed, no holes are injected at the face where the hole injection layer and carrier suppression layer BF make contact due to the difference in the work function thereof. By suppressing a current component that does not depend on the voltage applied to the auxiliary electrode 2, the OFF current can be reduced and the ON/OFF ratio of the brightness can be improved.

Although a specified carrier suppression layer is provided in this embodiment, the carrier suppression layer may have a structure that further reduces the leakage current between the anode and cathode by forming the insulation film on the anode with substantially the same shape as the anode.

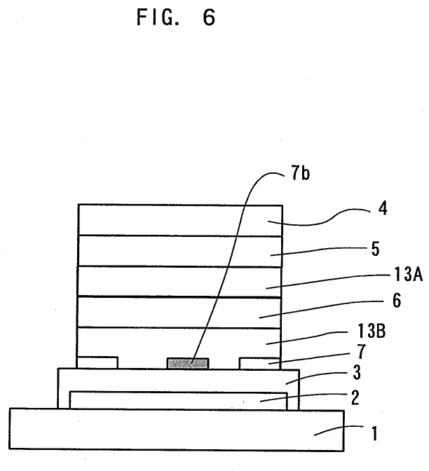

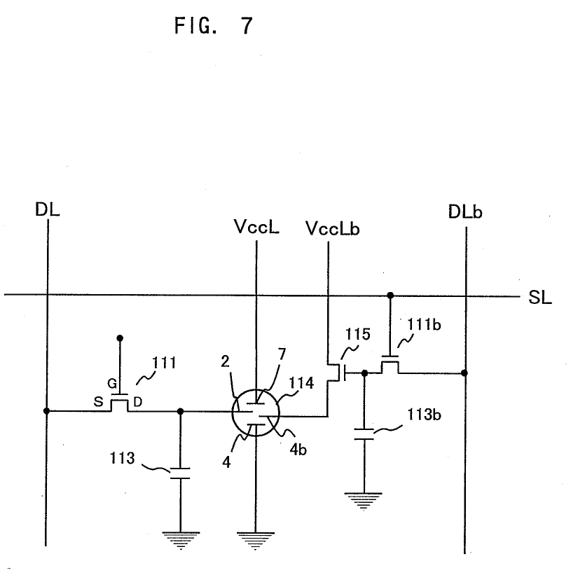

Moreover, a further embodiment can also be constituted by establishing a stacking order that is the reverse of that described above, i.e. from the anode to the cathode. As shown in FIG. 6, the organic EL element 114 is obtained by forming, in order, the auxiliary electrode 2, insulation layer 3, cathode 7 (first electrode) and a second cathode 7b (third electrode), the electron injection layer 13B, light emission layer 6, hole transport layer 13A, hole injection layer 5, and anode 4 (second electrode) on the substrate 1.

It should be noted that, although an example in which one anode or cathode is added as the third electrode in this embodiment, two or more anodes or cathodes connected to another certain control circuit can also be used as the third electrode.

Furthermore, although a light-emitting element is indicated in this embodiment, a plurality of light-emitting elements can also be used for the pixels of the display device. More specifically, if there is at least one organic transistor and the required elements such as capacitors, as well as pixel electrodes are manufactured on a common substrate, the active drive-type display device of the present invention can be implemented. As an example, a structure for a case where the present invention is applied to a display device will be described hereinbelow.

FIG. 7 shows an equivalence circuit diagram that shows a light emission section of a subpixel of an organic EL display panel that uses a structure in which the respective first and second anodes 4 and 4b are electrically connected to different circuits in the organic EL element 114 shown in FIG. 2.

Each of the light-emitting sections formed on the substrate is constituted by a selective transistor switching organic TFT element 111, data voltage holding capacitors 113 and 113b, an organic EL element 114, and a grayscale control switching organic TFT element 115. The light-emitting section of the pixel can be implemented by arranging the constitution in the vicinity of the respective intersections between the scan lines SL, first and second supply lines VccL and VccLb, and first and second signal lines DL and DLb.

The gate electrodes of the first and second switching organic TFT elements 111 and 111b are connected to scan line SL that supplies an address signal and the source electrodes of the first and second switching organic TFT elements 111 and 111b are connected to the first and second signal lines DL and DLb. The drain electrode of the first switching organic TFT element 111 is connected to the first auxiliary electrode 2 of the organic EL element 114 and one terminal of the capacitor 113.

The drain electrode of the second switching organic TFT element 111b is connected to the gate electrode of the grayscale control switching organic TFT element 115 and to one terminal of the capacitor 113b. The other of the capacitors 113 and 113b is grounded.

The source electrode of the grayscale control switching organic TFT element 115 is connected to the second supply line VccLb. The drain electrode of the grayscale control switching organic TFT element 115 is connected to the second anode 4b of the organic EL element 114.

The cathode 7 of the organic EL element 114 is connected to the first and second supply lines VccL and VccLb and the respective first and second anodes 4 and 4b of the organic EL element 114 are grounded.

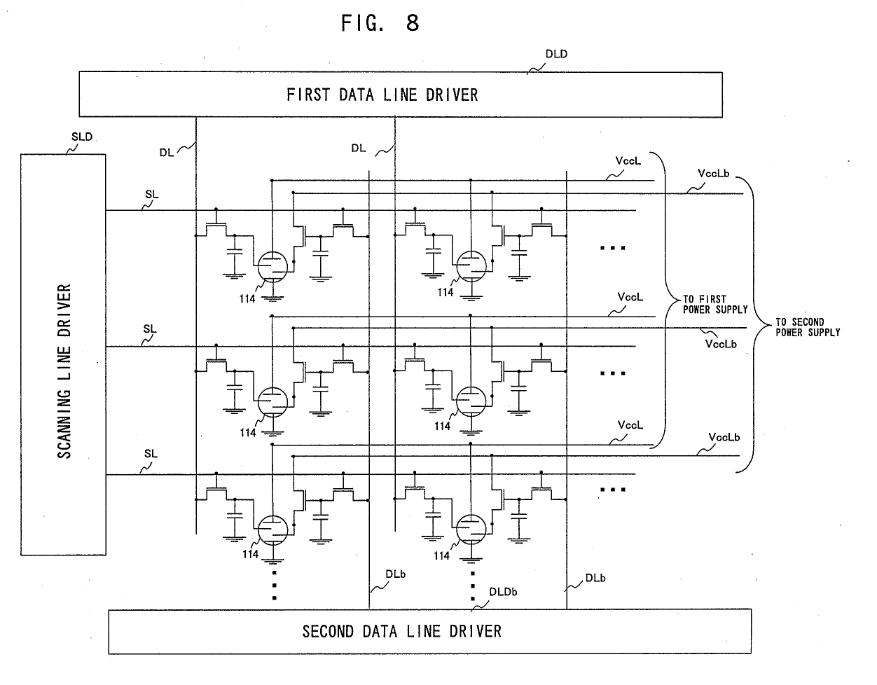

FIG. 8 shows a constitutional view of an organic EL display panel in which are arranged a plurality of light-emitting sections of FIG. 7 (organic EL elements 114) and which uses same as pixels. Each of the scanning lines SL is connected to a scanning line driver SLD, the first and second signal lines DL and DLb are connected to first and second data line drivers DLD and DLDb, and the first and second supply lines VccL and VccLb are connected to the first and second supplies.

The organic TFT element 111 comprises opposing source electrode S and drain electrode D that are fabricated together with the organic EL element 114 on the substrate of the organic EL display panel, an organic semiconductor film that comprises an organic semiconductor that is stacked so that a channel can be formed between the source and drain electrodes, and a gate electrode G capable of applying an electric field to the organic semiconductor film between the source electrode S and drain electrode D, comprising a gate insulation film that covers the gate electrode G and insulates same from the source electrode S and drain electrode D.

### First Embodiment

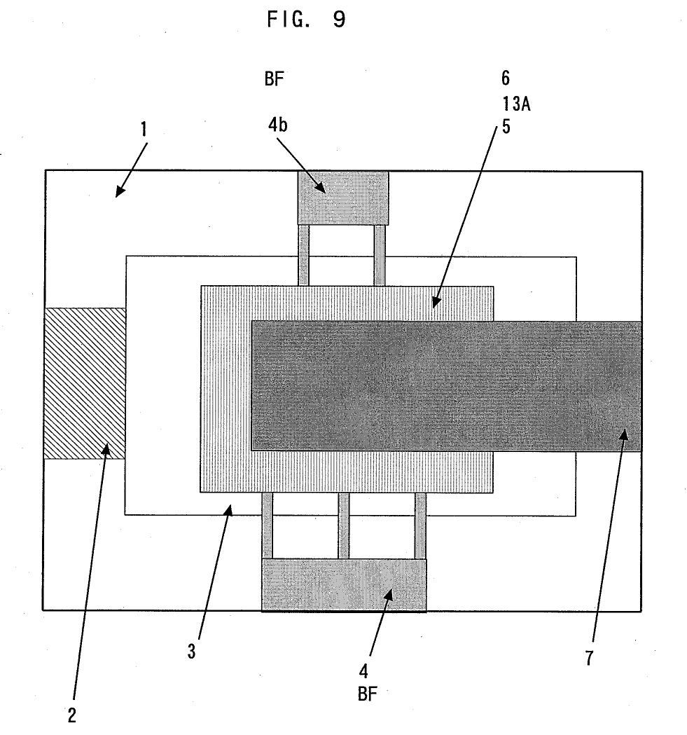

A light-emitting element that uses an insulation film as a carrier suppression layer as shown in FIG. 3 was fabricated. FIG. 9 is a planar view from the substrate side of the second light-emitting element in FIG. 2. As shown in FIG. 14, the first and second anodes 4 and 4b are formed with a comb shape or blind shape but may have a grating shape and, if the anodes have a grating shape, comb shape or blind shape, a pattern for the carriers passing through the organic semiconductor layer can be demarcated.

A light-emitting element of this kind was fabricated using steps (1) to (7).

(1) Formation of auxiliary electrode: after forming an ITO on a nonalkali glass substrate with a thickness of 100 nm by means of sputtering, a photoresist was applied by means of spin coating. The former photoresist was patterned by means of exposure using an optical mask and development, the ITO film of parts without the photoresist pattern was removed from above by means of milling, and the photoresist was finally dissolved by using a detachment solution.

(2) Formation of the insulation layer: the insulation layer was deposited with a thickness of 300 nm by means of spin coating using a polyvinylphenole polymer 8 wt % propylene glycol monomethyl ester acetate (PGMEA) solution. Thereafter, the polymer film deposited at the end on the auxiliary electrode was sampled using cotton containing PGMEA and baking was performed for 180 minutes at 200° C. by using a hot plate.

(3) Formation of first and second anodes: The anodes were formed by depositing metal with a thickness of 50 nm by means of vacuum vaporization using a metal mask. The metal deposition speed was 0.1 m/s. Thereafter, SiO₂ was deposited with a thickness of 100 nm as a carrier suppression layer (insulation film) by means of vacuum deposition using an electron beam by using the same mask. The deposition speed of the SiO₂ at this time was 0.2 nm/s.

(4) Formation of the hole injection layer: Petacene was deposited with a thickness of 50 nm for the hole injection layer. The deposition speed of the petacene at this time was 0.1 nm/s.

(5) Formation of the hole transport layer: α-NPD was deposited with a thickness of 50 nm for the hole transport layer.

(6) Formation of the light emission layer: Tris(8-quino-linato) aluminum was deposited as the light emission layer material with a thickness of 60 nm by means of vacuum deposition.

(7) Formation of cathode: for the cathode, aluminum was evaporated with a thickness of 100 nm by means of vacuum deposition. Here, the deposition speed of silver was 0.3 nm/s.

### Second Embodiment

The light-emitting element shown in FIG. 6 was fabricated in the following steps (1) to (8).

(1) Formation of the auxiliary electrode: after forming an ITO on a nonalkali glass substrate with a thickness of 100 nm by means of sputtering, the ITO was patterned as per the first embodiment.

(2) Formation of the insulation layer: for the insulation layer, SiO₂ was deposited with a thickness of 300 nm by means of sputtering. Thereupon, the deposition range was limited by using a metal mask so that the insulation layer would not be deposited on part of the auxiliary electrode.

(3) Fabrication of the first and second cathodes: for the cathode, magnesium and silver were co-evaporated with a thickness of 20 nm in the ratio 10:1 by means of vacuum deposition. There upon, the deposition speed of the magnesium was 1 nm/s and the deposition speed of the silver was 0.1 nm/s. Thereafter, platinum was evaporated with a thickness of 20 nm by using the same mask.

(4) Formation of electron injection layer: for the electron injection layer, a carbon film of fullerene C60 was deposited by means of vacuum deposition.

(5) Formation of light-emitting layer: for the light emission layer material, tris (8-quino-linato) aluminum (Alq3) and coumarin (C545T) were co-evaporated by means of vacuum deposition and deposited with a thickness of 40 nm. The concentration of the coumarin (C545T) at such time was 3 wt %. The deposition speed of the Alq3 was 0.3 nm/s.

(6) Formation of the hole transport layer: for the hole transport layer, α-NPD was deposited by means of vacuum deposition using a 50 nm metal mask.

(7) Formation of hole injection layer: for the hole injection layer, CuPc was deposited by means of vacuum deposition by using a 30 nm metal mask.

(8) Formation of anodes: for the anodes, IZO was deposited with a thickness of 30 nm by means of vacuum deposition.

1. A light-emitting element that comprises a light emission layer that is deposited between first and second electrodes that lie opposite one another in parallel; an organic semiconductor layer that is deposited between the light emission layer and the first electrode; and an auxiliary electrode that is disposed via an insulation layer on the opposite side of the face of the first electrode opposite the second electrode, the light-emitting element further comprising:
a third electrode that is disposed inside the organic semiconductor layer.

2. The light-emitting element according to claim 1, wherein the first and second electrodes are an anode and a cathode and the organic semiconductor layer is a hole injection layer, a hole transport layer, or stacked layers thereof.

3. The light-emitting element according to claim 2, further comprising:
an auxiliary organic semiconductor layer that is deposited between the light emission layer and the second electrode,
wherein the auxiliary organic semiconductor layer is an electron injection layer, an electron transport layer or stacked layers thereof.

4. The light-emitting element according to claim 1, wherein the first electrode and the second electrode are a cathode and an anode and the organic semiconductor layer is an electron injection layer, an electron transport layer or stacked layers thereof.

5. The light-emitting element according to claim 4, further comprising an auxiliary organic semiconductor layer that is deposited between the light emission layer and the second electrode,
wherein the auxiliary organic semiconductor layer is a hole injection layer, a hole transport layer, or stacked layers thereof.

6. The light-emitting element according to claim 1, wherein the first and third electrodes have a grating shape, a comb shape or a blind shape.

7. The light-emitting element according to claim 1, wherein the second and third electrodes comprise a transparent material or a semitransparent material.

8. The light-emitting element according to claim 1, further comprising a carrier suppression layer that is inserted between the first and third electrodes, and the organic semiconductor layer such that the carrier suppression layer is in contact with the first and third electrodes and the organic semiconductor layer.

9. The light-emitting element according to claim 1, wherein the first and third electrodes are connected to mutually different power supplies.

10. A display device in which a plurality of light-emitting sections are disposed in a matrix shape,
wherein each of the light-emitting sections is a light-emitting element that comprises a light emission layer that is deposited between first and second electrodes that lie opposite one another in parallel, an organic semiconductor layer that is deposited between the light emission layer and the first electrode, and an auxiliary electrode that is disposed via an insulation layer on the opposite side of the face of the first electrode opposite the second electrode, the light-emitting element further comprising a third electrode that is disposed inside the organic semiconductor layer.

11. The display device according to claim 10, further comprising a switching element electrically connected to the auxiliary electrode, wherein the switching element is provided in each of the light-emitting sections, and the display device further comprises wiring that supplies electrical power to the pair of electrodes and wiring for applying ON/OFF voltage information to the switching element.

12. A light-emitting element that comprises a light emission layer that is deposited between first and second electrodes that lie opposite one another in parallel, and an auxiliary electrode that is disposed via an organic semiconductor layer and insulation layer on the opposite side of the face of the first electrode opposite the second electrode, the light-emitting element further comprising:
a third electrode that is disposed inside the organic semiconductor layer.

13. The light-emitting element according to claim 12, wherein the first and second electrodes are an anode and a cathode and the organic semiconductor layer is a hole injection layer.

14. The light-emitting element according to claim 13, further comprising an auxiliary organic semiconductor layer that is deposited between the light emission layer and the second electrode,
wherein the auxiliary organic semiconductor layer is an electron injection layer, an electron transport layer, or stacked layers thereof.

15. The light-emitting element according to claim 12, wherein the first and second electrodes are a cathode and an anode, and the organic semiconductor layer is an electron injection layer.

16. The light-emitting element according to claim 15, further comprising an auxiliary organic semiconductor layer that is deposited between the light emission layer and the second electrode,
wherein the auxiliary organic semiconductor layer is a hole injection layer, a hole transport layer, or stacked layers thereof.

17. The light-emitting element according to claim 12, wherein the first and third electrodes have a grating shape, a comb shape or a blind shape.

18. The light-emitting element according to claim 12, wherein the second and third electrodes comprise a transparent material or a semitransparent material.

19. The light-emitting element according to claim 12, further comprising a carrier suppression layer that is inserted between the first and third electrodes, and the organic semiconductor layer such that the carrier suppression layer is in contact with the first and third electrodes and the organic semiconductor layer.

20. The light-emitting element according to claim 12, wherein the first and third electrodes are connected to mutually different power supplies.

21. A display device in which a plurality of light-emitting sections are disposed in a matrix shape,
wherein each of the light-emitting sections is a light-emitting element that comprises a light emission layer that is deposited between first and second electrodes that lie opposite one another in parallel, and an auxiliary electrode that is disposed via an organic semiconductor layer and an insulation layer on the opposite side of the face of the first electrode opposite the second electrode, the light-emitting element further comprising:
a third electrode that is disposed inside the organic semiconductor layer.

22. The display device according to claim 21, wherein a switching element that is electrically connected to the auxiliary electrode is provided in each of the light-emitting sections, and the display device further comprises wiring that supplies electrical power to the pair of electrodes and wiring for applying ON/OFF voltage information to the switching element.
